(19) United States
(12) Patent Application Publication
(10) Pub. No.: US 2013/0088833 A1
(43) Pub. Date: Apr. 11, 2013

(54) FLEXIBLE AIR DUCT FOR EQUIPMENT COOLING

(71) Applicants: Aaron Cox, Tucson, AZ (US); Joni Saylor, Tucson, AZ (US); Kevin Schultz, Research Triangle Park, NC (US); Jason Minyard, Tucson, AZ (US); Camillo Sassano, Research Triangle Park, NC (US)

(72) Inventors: Aaron Cox, Tucson, AZ (US); Joni Saylor, Tucson, AZ (US); Kevin Schultz, Research Triangle Park, NC (US); Jason Minyard, Tucson, AZ (US); Camillo Sassano, Research Triangle Park, NC (US)

(73) Assignee: INTERNATIONAL BUSINESS MACHINES CORPORATION, Armonk, NY (US)

(21) Appl. No.: 13/253,496

(22) Filed: Oct. 5, 2011

(51) Int. Cl. H05K 7/20; F28F 1/00

(52) U.S. Cl. 361/689; 165/177

(57) ABSTRACT

A server cooling system may include, but is not limited to: a server rack; and a flexible duct apparatus, the flexible duct apparatus comprising: a flexible frame; and a fabric portion disposed over at least a portion of the frame, wherein the flexible frame and fabric cooperatively define at least a cooling system aperture and a server aperture.

### BACKGROUND

Management of air cooling systems in data centers is a growing concern. Servers can produce large amounts of heat during the course of normal operation that must be removed in order to ensure peak performance. In many cases this involves blowing cooled air onto the servers which removes the generated heat. The air warmed by the servers is then directed back to the cooling system for heat removal and recirculation back to the servers. Previous methods for establishing a defined channel for recirculated air include installing rigid metal ducts and access ducts. These ducts and ducts direct air from a cooling medium supply into the server rack and/or hot server exhaust air away from the servers and into a return air path, or otherwise away from the servers. The size and rigidity of these ducts and ducts can cause reduced access to equipment. Rigid access ducts may also be bulky and duct swing clearance may be small due to the obstructions provided by other rigid ducts and ducts. Bulky metal ducts and ducts may also take up space that could otherwise be used for servers or other equipment. The rigidity of the metal ducts can limit the flexibility of the placement of server racks. Because of the well defined shape and length of certain pieces of rigid metal duct, there may be limited places that a server rack could be placed to allow a connection to the air circulation system.

### SUMMARY

The present disclosure describes a flexible air duct system and a server system installation method that provides for easy installation, better access to equipment, and flexibility of server rack placement. Elements of the system may include, but are not limited to: a server rack; and a flexible duct apparatus, the flexible duct apparatus comprising: a flexible frame; and a fabric portion disposed over at least a portion of the frame, wherein the flexible frame and fabric cooperatively define at least a cooling system aperture and a server aperture.

### BRIEF DESCRIPTION OF THE DRAWINGS

The numerous advantages of the disclosure may be better understood by those skilled in the art by reference to the accompanying figures in which:

FIG. 1 shows a flexible duct.

FIG. 2 shows a flexible duct attached to a server rack.

FIG. 3A shows a flexible duct configured for channeling a cooling medium from a floor vent into a server rack.

FIG. 3B shows a flexible duct directing air from a floor vent through a server rack.

FIG. 4 shows a flexible duct directing air from a server rack to a return air path.

FIGS. 5A and 5B show flexible ducts used in varying cooling system configurations.

FIG. 6A shows an opened server rack door including a flexible duct attached to a server rack.

FIG. 6B shows an opened server rack door including a flexible duct attached to a server rack via a mechanical hinge.

### DETAILED DESCRIPTION

Reference will now be made in detail to the subject matter disclosed, which is illustrated in the accompanying drawings.

It is believed that the present invention and many of its attendant advantages will be understood by the foregoing description. It may be also believed that it will be apparent that various changes may be made in the form, construction and arrangement of the components thereof without departing from the scope and spirit of the invention or without sacrificing all of its material advantages. The form herein before described being merely an explanatory embodiment thereof. It may be the intention of the following claims to encompass and include such changes.

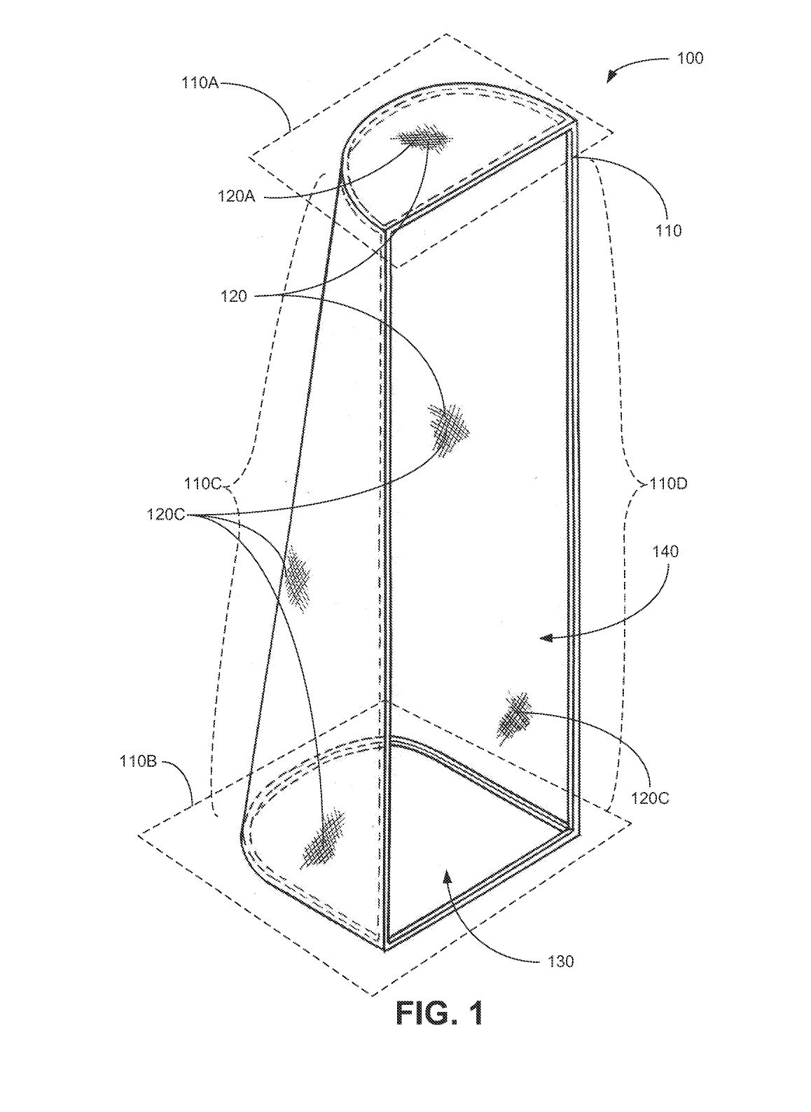

FIGS. 1-6B provide graphical representations of various embodiments of the invention.

FIG. 1 depicts a flexible duct 100. The duct 100 may include collapsible frame 110 and fabric 120. The fabric 120 may be selected from any flexible fabric (e.g. nylon, vinyl, canvas, etc.). The fabric 120 may be cut in a shape and size that closely conforms to one or more surfaces defined by collapsible frame 110. The fabric 120 may be cut so that the top horizontal portion 110A of collapsible frame 110 is covered in fabric 120A while the bottom portion 110B of collapsible frame 110 is at least partially free of fabric, thereby defining a cooling system aperture 130. The fabric 120C may further cover an at least partially curved surface 110C of collapsible frame 110 while a frontal portion 110D of collapsible frame 110 may be at least partially free of fabric, thereby defining a server aperture 140. The cooling system aperture 130 and the server aperture may cooperate to provide a conduit for a cooling medium (e.g. air, nitrogen, CO₂, or any other gaseous cooling product).

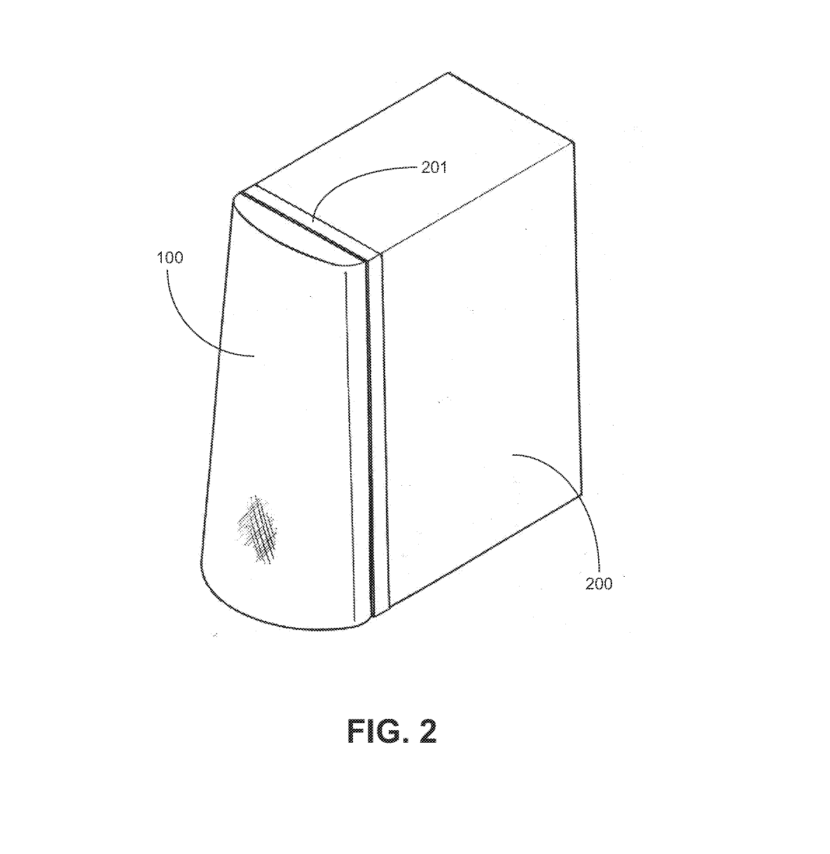

FIG. 2 shows the flexible duct 100 installed on a surface of a server rack 200. The flexible duct 100 may be designed to fit snugly on the front or back of a server rack 200. For example, one or more flexible gaskets may be disposed between the flexible duct 100 and the server rack 200. Means for attachment of flexible duct 100 to the server rack 200 may include one or more snaps, clips, clamps, hooks, clasps, flanges, grommets, pins, captive fasteners, retaining rings, banding, strapping, ties, zippers or other established techniques. The flexible duct 100 may be installed on the server rack 200 such that the flexible duct remains in a substantially static position relative to at least a portion of the server rack 200. For example the flexible duct 100 may be secured to the server rack 200 by the means for attachment around the perimeter of the portion of the flexible duct 100 defining the server aperture 140. More specifically, the flexible duct 100 may be coupled to an existing vented door portion 201 of the server rack 200. Such a configuration may allow for increased cooling of the server rack 200 while retaining the door portion 201.

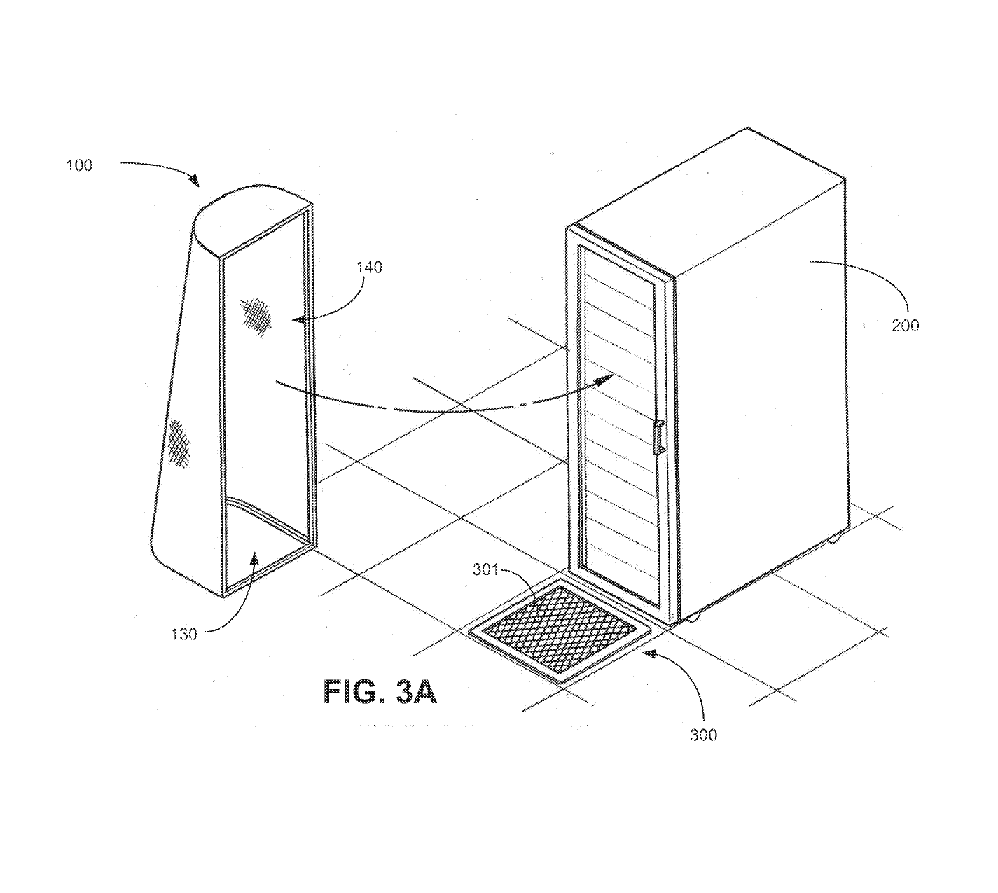

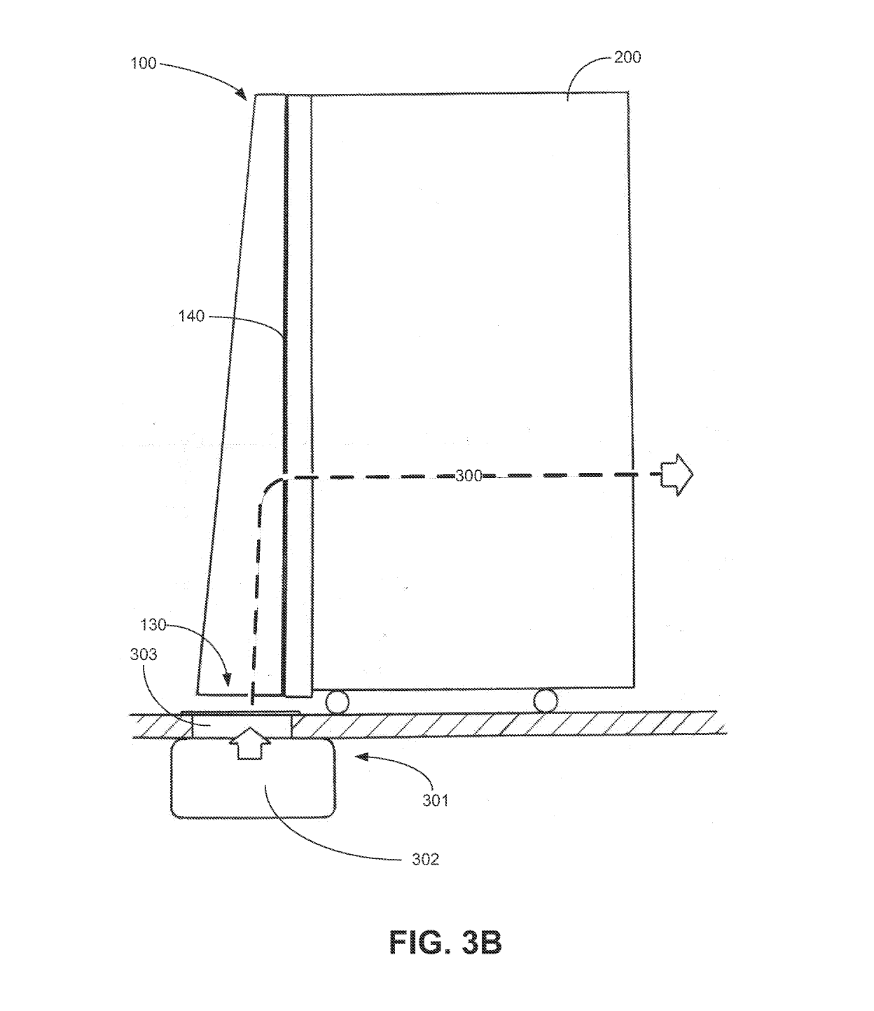

As shown in FIGS. 3A and 3B, the flexible duct 100 may be used to channel a cooling medium 300 from a cooling medium supply 301 (e.g. a plenum 302 supplying a cooling medium through an interface such as a grate 303) through heat generating areas of a server rack 200. Air may enter system aperture 230 and leave through server aperture 140.

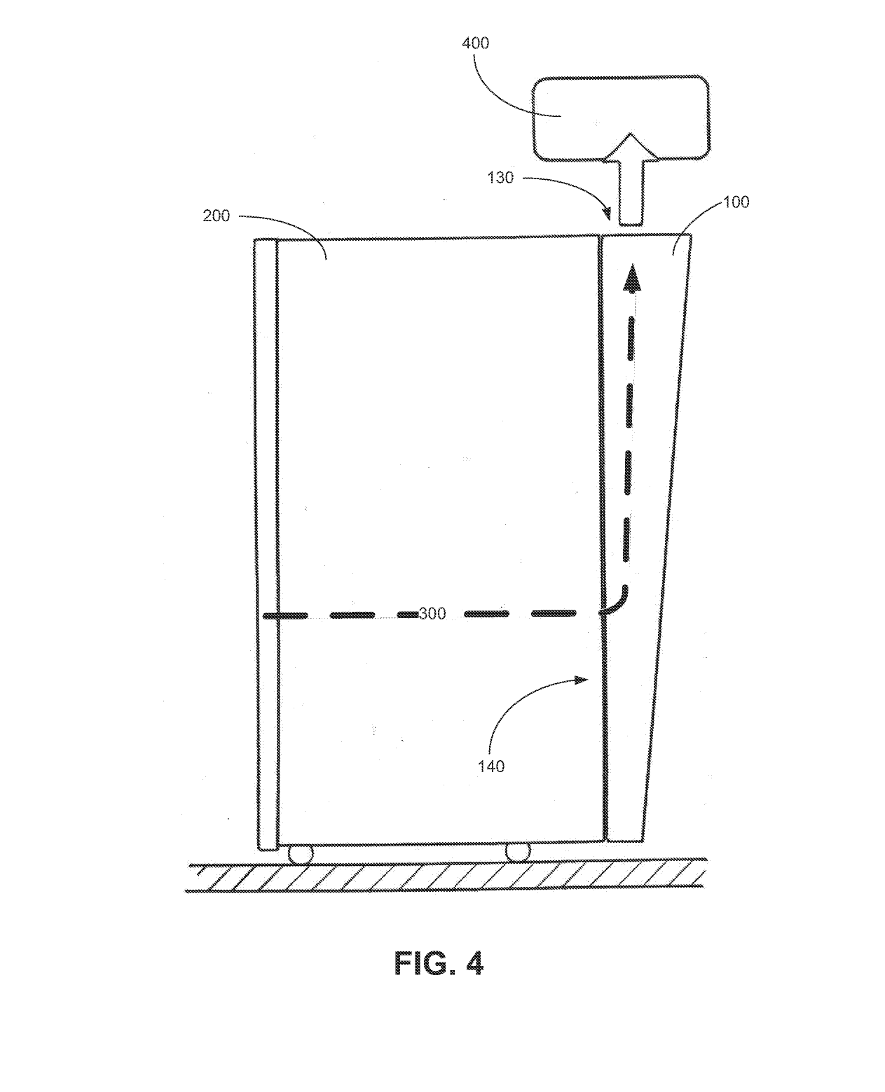

FIG. 4 shows how flexible duct 100 may be installed onto a surface of the server rack 200 in order to channel warmed air into a return air path 400 near a ceiling. The cooling medium 300 from the server rack 200 may enter flexible duct 100 through server aperture 140 and leave through cooling system aperture 130.

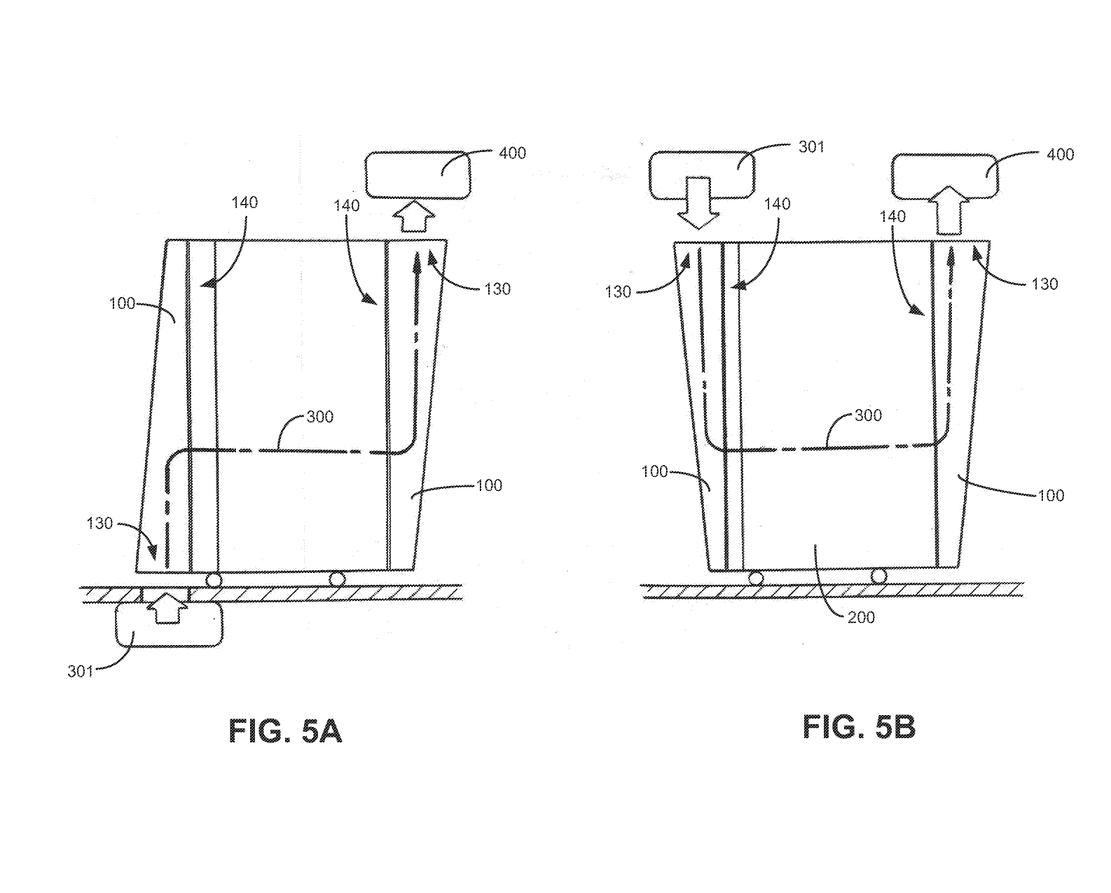

FIGS. 5A and 5B depict various cooling medium 300 circulation patterns for cooling of a server rack 200. As shown in FIG. 5A, cooling medium supply 301 may be found at the floor while the return air path 400 may be found near the ceiling. In this case, the flexible duct 100 installed on a first surface of the server rack 200 may be oriented so that the cooling system aperture 130 is placed on the floor above cooling medium supply 301. The flexible duct 100 installed on a second surface of the server rack 200 may be oriented so that cooling system aperture 130 is placed directly below a return air path 400. Connections between system apertures 130 and cooling medium supplies 301 or return air paths 400 may be implemented with flexible ducts similar in construction to flexible duct 100.

FIG. 5B shows a server room configuration where both the cooling medium supply 301 and return air paths 400 are found near the ceiling. In this case, both flexible ducts 100 may be installed so that the cooling system aperture 130 is facing up to accommodate the cooling medium supply 301 and return air path 400. Alternatively, both flexible ducts 100 may be installed so that the cooling system aperture 130 is facing down to accommodate a cooling medium supply 301 and return air path 400 which are located in a floor (not shown).

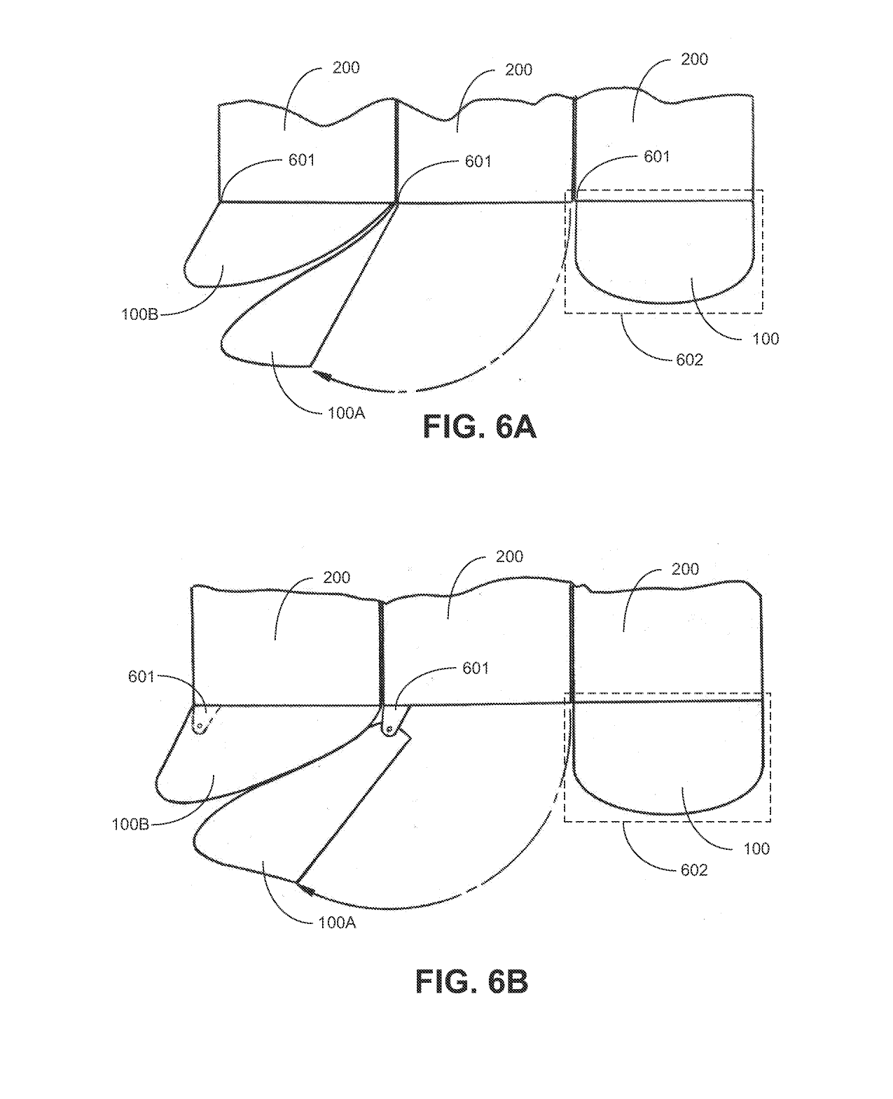

FIGS. 6A and 6B depict a row of server racks 200 placed side by side as is common practice. A flexible duct 100 may be attached to a server rack 200 via one or more mechanical hinges 601 to form a flexible door 602 including the flexible duct 100 that is configured to rotate the flexible duct 100 away from the server rack 200. As shown in FIG. 6A, a technician may be able to open flexible duct 100A at an angle greater than would be possible if duct 100A were not comprised of flexible materials (e.g. a rigid metal construction). An open flexible duct 100A may at least partially deform as it is opened and pushed up against another flexible duct 100B. Closed flexible duct 100B may also at least partially deform as flexible duct 100A is pushed against it. As the flexible duct 100B is closed, both flexible ducts 100A and 100B may elastically return their original shape once any opening forces are removed. The flexible nature of ducts 100 provide improved access to server rack 200 (e.g. for servicing).

It is believed that the present invention and many of its attendant advantages will be understood by the foregoing description. It may be also believed that it will be apparent that various changes may be made in the form, construction and arrangement of the components thereof without departing from the scope and spirit of the invention or without sacrificing all of its material advantages. The form herein before described being merely an explanatory embodiment thereof. It may be the intention of the following claims to encompass and include such changes.

1. A flexible duct apparatus comprising:
a flexible frame; and
a fabric portion disposed over at least a portion of the frame,
wherein the flexible frame and fabric cooperatively define at least one of a cooling system aperture and a server aperture, and
wherein the flexible duct is removably couplable to a server rack.

2. The flexible duct apparatus of claim 1, wherein the flexible duct is configured for at least one of: directing a cooling medium from the server aperture to the cooling system aperture and directing a cooling medium from the cooling system aperture to the server aperture.

3. The flexible duct apparatus of claim 1, wherein the collapsible frame is composed at least one of spring steel, fiberglass, or plastic.

4. The flexible duct apparatus of claim 1, wherein the flexible duct apparatus is configured to direct a cooling medium from a cooling medium supply through a server rack.

5. The flexible duct apparatus of claim 4, wherein the cooling medium supply is located below the server rack.

6. The flexible duct apparatus of claim 4, wherein the cooling medium supply is located above the server rack.

7. The flexible duct apparatus of claim 1, wherein the flexible duct apparatus is configured to direct the cooling medium from a server rack to a return path.

8. The flexible duct apparatus of claim 7, wherein the return path is located above the server rack.

9. The flexible duct apparatus of claim 1, wherein the flexible duct apparatus is deformable upon an application of force to the flexible duct apparatus.

10. The flexible duct apparatus of claim 9, wherein the flexible duct apparatus is configured to elastically reform its shape after said force applied to flexible duct apparatus ceases.

11. A server system comprising:
a server rack; and
a flexible duct apparatus, the flexible duct apparatus comprising:
a flexible frame; and
a fabric portion disposed over at least a portion of the frame,
wherein the flexible frame and fabric cooperatively define at least a cooling system aperture and a server aperture.

12. The server system of claim 11, wherein the flexible duct is removably couplable to a server rack.

13. The server system of claim 11, wherein the flexible duct is configured for at least one of: directing a cooling medium from the server aperture to the cooling system aperture and directing a cooling medium from the cooling system aperture to the server aperture.

14. The server system of claim 11, wherein the collapsible frame is composed at least one of spring steel, fiberglass, or plastic.

15. The server system of claim 11, wherein the flexible duct apparatus is configured to direct a cooling medium from a cooling medium supply through a server rack.

16. The server system of claim 15, wherein the cooling medium supply is located below the server rack.

17. The server system of claim 15, wherein the cooling medium supply is located above the server rack.

18. The server system of claim 11, wherein the flexible duct apparatus is configured to direct the cooling medium from a server rack to a return path.

19. The server system of claim 18, wherein the return path is located above the server rack.

20. The server system of claim 11, wherein the flexible duct apparatus is deformable upon an application of force to the flexible duct apparatus.

21. The server system of claim 20, wherein the flexible duct apparatus is configured to elastically reform its shape after said force applied to flexible duct apparatus ceases.

22. The server system of claim 11, wherein the flexible duct is configured to rotate relative to the server rack.

23. The server system of claim 22, wherein the flexible duct forms a door of the server rack.
